(19) United States
(12) Patent Application Publication
(10) Pub. No.: US 2015/0382454 A1
(43) Pub. Date: Dec. 31, 2015

(54) SPILLED ADHESIVE GUIDE STRUCTURE OF FLEXIBLE CIRCUIT BOARD

(71) Applicant: ADVANCED FLEXIBLE CIRCUITS CO., LTD., TAOYUAN COUNTY (TW)

(72) Inventors: KUO-FU SU, TAOYUAN COUNTY (TW); CHIH-HENG CHUO, TAOYUAN COUNTY (TW)

(21) Appl. No.: 14/704,179

(22) Filed: May 5, 2015

(30) Foreign Application Priority Data
Jun. 26, 2014 (TW) 103122003

(51) Int. Cl. H05K 1/02; H05K 1/11

(52) U.S. Cl. CPC H05K 1/0272; H05K 1/111; H05K 1/113; H05K 2201/05

(57) ABSTRACT

Disclosed is a spilled adhesive guide structure of a flexible circuit board. At least one contact pad is formed in a conductive circuit trace arranged on a substrate of the flexible circuit board. The substrate includes an insulation coverlay adhesively bonded thereon by an adhesive layer. The conductive circuit trace includes at least one spilled adhesive guide structure formed therein adjacent to the contact pad so that when the insulation coverlay is adhesively bonded by the adhesive layer to the conductive circuit trace, a spilled adhesive partially spilled out from the adhesive layer is guided into the spilled adhesive guide structure to prevent the spilled adhesive of the adhesive layer from covering a surface of the contact pad.

### BACKGROUND OF THE INVENTION

1. Field of the Invention

The present invention relates to a structure of a flexible circuit board, and in particular to a flexible circuit board provided with a spilled adhesive guide structure. When an insulation coverlay is bonded on a substrate by an adhesive layer, a spilled adhesive partially spilled out from the adhesive layer is guided into the spilled adhesive guide structure to prevent the spilled adhesive of the adhesive layer from covering a surface of a contact pad.

2. The Related Arts

Flexible circuit boards have been widely used in all sorts of electronic products, especially those electronic products that are light and compact, such as consumer electronic products, including mobile phones, digital cameras, computer peripherals, flat displays, and game machine, all involve the use of the flexible circuit boards. A conventional structure of the flexible circuit boards generally comprises conductive circuit traces laid on a substrate. The conductive circuit traces include signal lines for transmission of electronic signals and also include power lines for supplying electrical power and grounding line for grounding. In certain applications, exposed contact pads may be defined in advance at predetermined sites of the conductive circuit traces to electrically conduct the signal lines or the grounding line.

As shown in FIGS. 1A-1D, in a prior art structure of a flexible circuit board, a number of conductive circuit traces, differential mode signal lines, and an insulation coverlay are formed on a substrate and then a grounding bridge over structure is formed thereon.

FIG. 1A is a schematic perspective view showing a pair of conductive circuit traces 11, 12 and differential mode signal lines 13, 14 are formed on a substrate 1, and then an insulation coverlay 3 is bonded on the substrate 1 by an adhesive layer 4. FIG. 1B is a schematic top plan view illustrating the conductive circuit traces 11, 12 and the differential mode signal lines 13, 14 are arranged on a top surface of the substrate 1 of FIG. 1A. FIG. 1C is a schematic top plan view illustrating a conductive material 5 is applied between the conductive circuit traces 11, 12 after the insulation coverlay 3 is applied on the substrate 1 of FIG. 1B. FIG. 1D is a cross-sectional view taken along line 1D-1D of FIG. 1C.

In the conventional grounding-bridged circuit board structure as shown in FIGS. 1A-1D, the conductive circuit traces 11, 12 are arranged on the substrate 1 to be isolated from and spaced from each other by a distance and at least a pair of differential mode signal lines 13, 14 are arranged between the conductive circuit traces 11, 12. The differential mode signal lines 13, 14 are arranged in a pairwise manner for transmission of high frequency differential mode signals. The conductive circuit traces 11, 12 are generally used as grounding lines. In addition to the differential mode signal lines 13, 14, the signal lines that are arranged between the conductive circuit traces 11, 12 may also be other signal lines, such as audio or video signal lines.

At least one contact pad 21, 22 is set up at a specific site of each conductive circuit trace 11, 12 respectively. The insulation coverlay 3 is bonded by an adhesive layer 4 to the substrate 1. The insulation coverlay 3 comprises openings 31, 32 corresponding to the contact pads 21, 22 respectively. A conductive material 5 is applied in the openings 31, 32 in such a way that the conductive material 5 is in contact engagement with the contact pads 21, 22 so as to electrically connect the conductive circuit traces 11, 12, achieving the purpose of bridging over the grounding lines.

Since the insulation coverlay 3 is bonded to the substrate 1 by the adhesive layer 4, in a process in which a pressure is applied to the adhesive layer 4, a spilled adhesive 41 may partially spill out from the adhesive layer 4 and spill over on an inner circumference of the openings 31, 32 (see FIG. 1D). Such adhesive spillover 41 may cover a part of the surface of the contact pads 21, 22. This may reduce the effective area of electrical contact of the contact pads 21, 22 and affect the electrical engagement to be established between the conductive material 5 and the surface of the contact pad 21, 22.

It is thus a challenge of the art to provide a solution to overcome the above problems.

### SUMMARY OF THE INVENTION

Thus, an object of the present invention is to provide a spilled adhesive guide structure of a flexible circuit board, which prevents spillover of adhesive occurring when an insulation coverlay is bonded by a layer of adhesive to a substrate of the flexible circuit board from covering a surface of a contact pad so as to enhance electrical engagement between the contact pad and a conductive material.

The technical solution that the present invention adopts to achieve the above object is that a substrate comprises at least one spilled adhesive guide structure formed in a conductive circuit trace and adjacent to a contact pad so that when an insulation coverlay is adhesively bonded by an adhesive layer to the substrate, adhesive spillover of the adhesive layer is guided into the spilled adhesive guide structure.

The contact pad can be a circular contact pad. a rectangular contact pad, or a gear like contact pad.

A conductive material is formed in an opening formed in the insulation coverlay and corresponding to the contact pad. The conductive material is filled in electrical engagement with a surface of the contact pad. The conductive material is selected from one of silver, aluminum, copper, tin, conductive carbon paste, and conductive particle contained adhesive.

In another embodiment of the present invention, the spilled adhesive guide structure is formed in an outer circumference of the contact pad.

The efficacy is that with the arrangement of the present invention, during the manufacturing and processing of a flexible circuit board, when an insulation coverlay is adhesively bonded by an adhesive layer to a substrate of the flexible circuit board, a spilled adhesive that might be induced by the adhesive layer is guided into and held in a spilled adhesive guide structure of the conductive circuit trace so as to prevent the spilled adhesive of the adhesive layer from covering a contact pad surface of the contact pad thereby enhancing electrical engagement between the contact pad and a conductive material.

### BRIEF DESCRIPTION OF THE DRAWINGS

The present invention will be apparent to those skilled in the art by reading the following description of preferred embodiments of the present invention, with reference to the attached drawings, in which:

FIG. 1A is a schematic perspective view showing a pair of conductive circuit traces and differential mode signal lines are formed on a substrate, and then an insulation coverlay is bonded on the substrate by an adhesive layer;

FIG. 1B is a schematic top plan view illustrating the conductive circuit traces and the differential mode signal lines arranged on the substrate of FIG. 1A;

FIG. 1C is a schematic top plan view illustrating a conductive material is applied between the conductive circuit traces after the insulation coverlay is bonded to the subs rate of FIG. 1B;

FIG. 1D is a cross-sectional view taken along line 1D-1D of FIG. 1C;

FIG. 2A is a schematic perspective view showing a conductive circuit trace and a pair of differential mode signal lines are formed on a substrate, an insulation coverlay is bonded on the substrate by an adhesive layer, and at least one spilled adhesive guide structure is formed in the conductive circuit trace according to a first embodiment of the present invention;

FIG. 2B is a schematic top plan view showing the insulation coverlay is formed on the substrate of FIG. 2A;

FIG. 2C is a cross-sectional view taken along line 2C-2C of FIG. 2B;

FIG. 2D is a cross-sectional view taken along line 2D-2D of FIG. 2B;

FIG. 2E is a cross-sectional view showing a conductive material is applied to the contact pad of FIG. 2D;

FIG. 3 is a schematic top plan view illustrating a second embodiment of the present invention;

FIG. 4A is a schematic perspective view showing a conductive circuit trace and a pair of differential mode signal lines are formed on a substrate, an insulation coverlay is bonded on the substrate by an adhesive layer, and at least one spilled adhesive guide structure is formed in the conductive circuit trace according to a third embodiment of the present invention;

FIG. 4B is a schematic top plan view showing the insulation coverlay is formed on the substrate of FIG. 4A;

FIG. 4C is a cross-sectional view taken along line 4C-4C of FIG. 4B;

FIG. 4D is a cross-sectional view taken along line 4D-4D of FIG. 4B;

FIG. 5A is a schematic perspective view showing a conductive circuit trace and a pair of differential mode signal lines are formed on a substrate, an insulation coverlay is bonded on the substrate by an adhesive layer, and at least one spilled adhesive guide structure is formed in the conductive circuit trace according to a fourth embodiment of the present invention;

FIG. 5B is a schematic top plan view showing the insulation coverlay is formed on the substrate of FIG. 5A;

FIG. 5C is across-sectional view taken along line 5C-5C of FIG. 5B; and

FIG. 5D is a cross-sectional view taken along line 5D-5D of FIG. 5B.

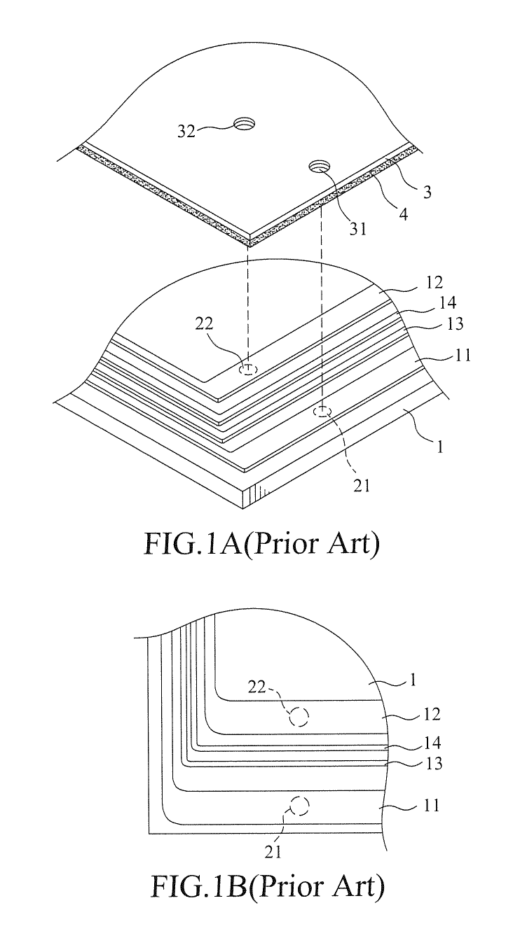

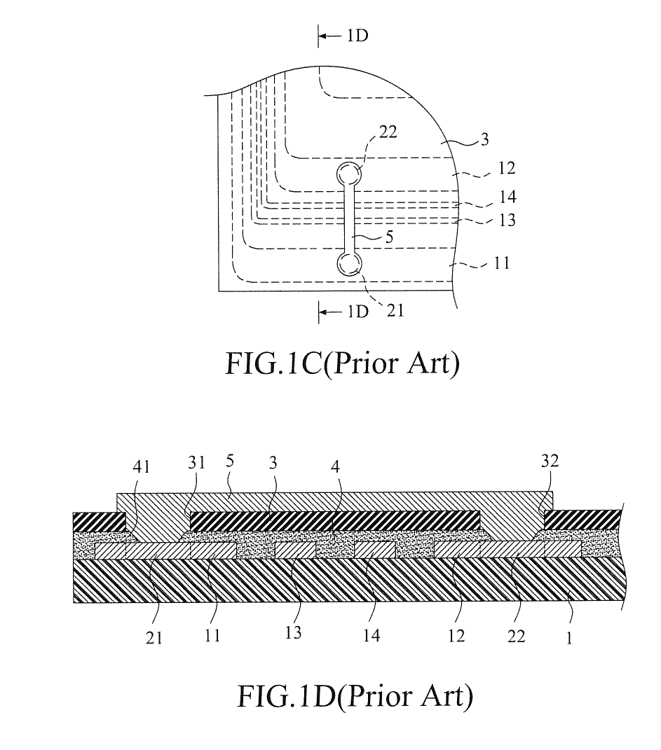

### DETAILED DESCRIPTION OF THE PREFERRED EMBODIMENTS

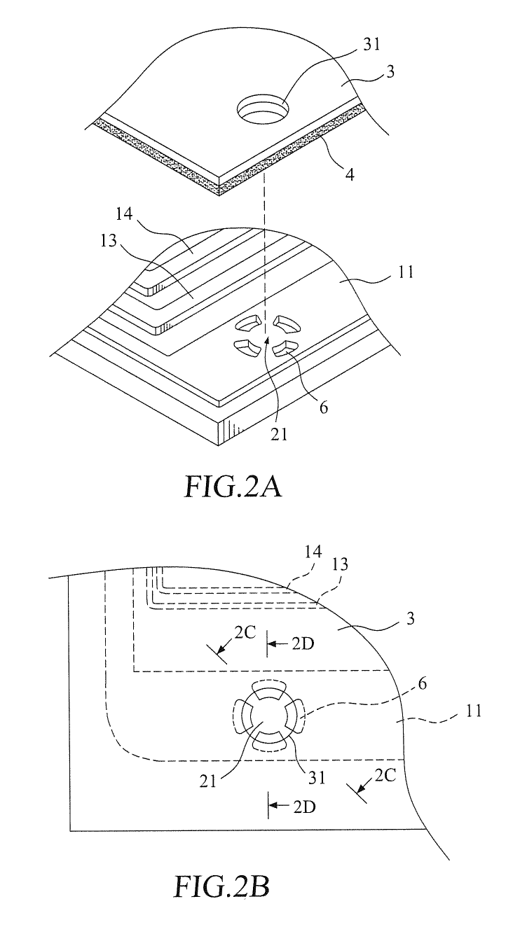

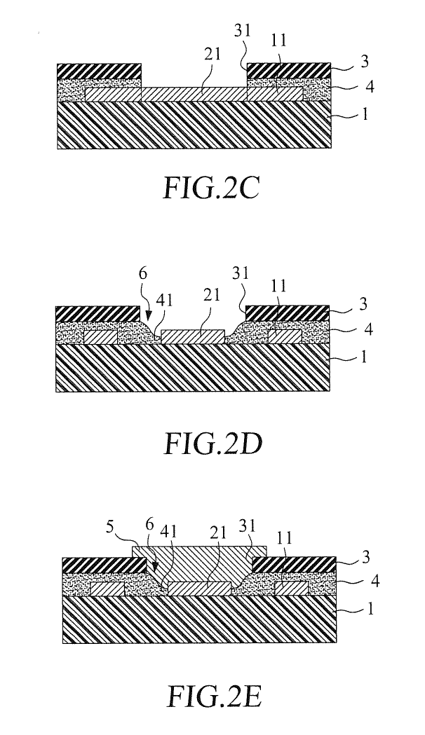

Referring to FIGS. 2A-2E, a conductive circuit trace 11 and a pair of differential mode signal lines 13, 14 are formed on a substrate 1. An insulation coverlay 3 is bonded on the substrate 1 by an adhesive layer 4.

The conductive circuit trace 11 comprises at least one contact pad 21 defined at a predetermined site and at least one spilled adhesive guide structure 6 formed therein adjacent to the contact pad 21 according to a first embodiment of the present invention.

In the example of the embodiment illustrated, the contact pad 21 is a circular contact pad having a circular contour or circumference. Four spilled adhesive guide structures 6 are formed in and spaced along the circular circumference of the contact pad 21. The contact pad 21 may alternatively be a gear-like solider pad having a toothed contour or circumference with a plurality of spilled adhesive guide structures defined in and with the toothed circumference.

FIG. 2C is a cross-sectional view taken along line 2C-2C of FIG. 2B and shows an insulation coverlay 3 is adhesively bonded by an adhesive layer 4 to the substrate 1. The insulation coverlay 3 comprises an opening 31 formed therein to correspond to the contact pad 21 in respect of the circular contour and diameter or size thereof, so as to expose the top surface of the contact pad 21.

FIG. 2D is a cross-sectional view taken along line 2D-2D of FIG. 2B and shows when the insulation coverlay 3 is adhesively bonded by the adhesive layer 4 to the conductive circuit trace 11, a spilled adhesive 41 of the adhesive layer 4 is guided into the spilled adhesive guide structures 6 to prevent the spilled adhesive 41 of the adhesive layer 4 from covering a surface of the contact pad 21.

The conductive circuit trace 11 can be made of a copper foil by means of an etching process. The spilled adhesive guide structures 6 can be formed in the process of etching the conductive circuit trace 11 by having predetermined portions corresponding to the spilled adhesive guide structures 6 etched off to form a recessed configuration.

FIG. 2E is a cross-sectional view illustrating a conductive material 5 is applied or formed on a portion of surface of the insulation coverlay 3 and in the opening 31 an that the conductive material 5 is filled in electrical contact engagement with the contact pad 21. The conductive material 5 can be selected from one of silver, aluminum, copper, tin, conductive carbon paste, and conductive particle contained adhesive.

Since the spilled adhesive 41 that occurs in adhesively bonding the insulation coverlay 3 to the conductive circuit trace 11 with the adhesive layer 4 is guided into and stored in the spilled adhesive guide structure 6 according to the present invention, the spilled adhesive 41 of the adhesive layer 4 is prevented from covering the surface of the contact pad 21 and thus excellent electrical engagement can be established between the conductive material 5 and the contact pad 21.

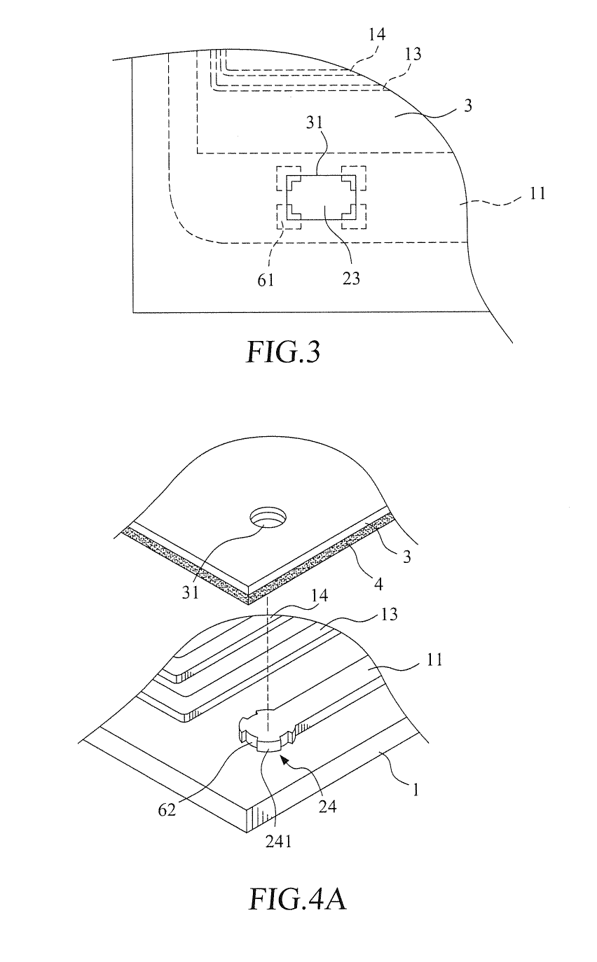

In the embodiment illustrated in FIGS. 2A-2E, the contact pad 21 is a circular contact pad having a circular outer circumference; however, a contact pad having an outer circumference of other shapes may be used equally. For example, FIG. 3 is a schematic top plan view illustrating a second embodiment of the present invention, in which the contact pad 23 is a rectangular contact pad and at least one spilled adhesive guide structure 61 formed at a location adjacent to the contact pad 23 (such as a trough being formed at each of four corners of the contact pad 23). This arrangement can similarly achieve the purpose of receiving and holding the adhesive spillover 41 of the adhesive layer 4 therein.

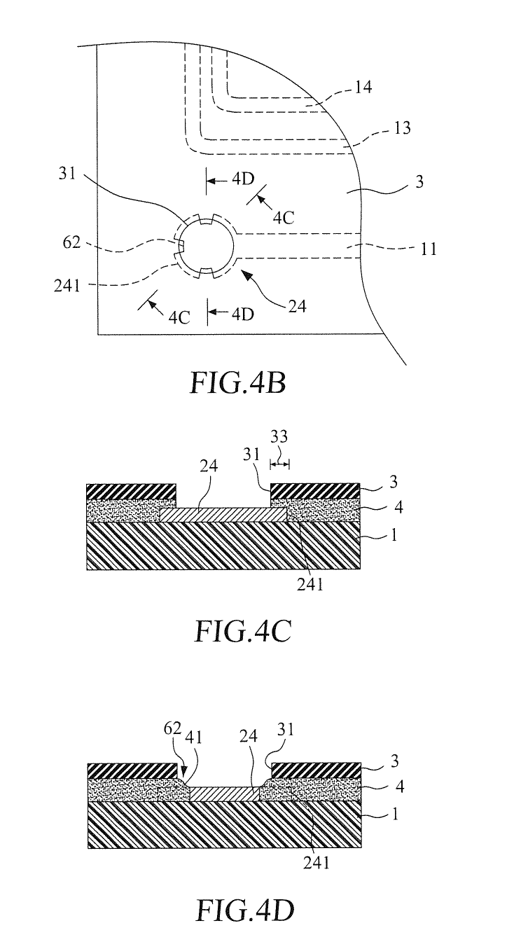

FIG. 4A is a schematic perspective view showing a conductive circuit trace and a pair of differential mode signal lines are formed on a substrate, an insulation coverlay is bonded on the substrate by an adhesive layer, and at least one spilled adhesive guide structure is formed in the conductive circuit trace according to the third embodiment of the present invention. FIG. 4B is a schematic top plan view showing the insulation coverlay is formed on the substrate of FIG. 4A. In the instant embodiment, at least one conductive circuit trace 11 is formed on the substrate 1 and at least one contact pad 24 is formed on the conductive circuit trace 11. The contact pad 24 has an outer circumference 241.

Referring to FIGS. 4C and 4D, FIG. 4C is a cross-sectional view taken along line 4C-4C of FIG. 4B and FIG. 4D is a cross-sectional view taken along line 4D-4D of FIG. 4B. The substrate 1 is adhesively bonded by an adhesive layer 4 to an insulation coverlay 3. The insulation coverlay 3 comprises an opening 31 formed therein to correspond to the outer circumference 241 of the contact pad 24.

The outer circumference 241 of the contact pad 24 comprises at least one spilled adhesive guide structure 62 formed therein to allow spilled adhesive 41 of the adhesive layer 4 occurring in adhesively bonding the insulation coverlay 3 to the conductive circuit trace 11 with the adhesive layer 4 to be guided into and held in the spilled adhesive guide structure 62 so as to prevent the spilled adhesive 41 of the adhesive layer 4 from covering the contact pad 24.

The formation of the spilled adhesive guide structure 62 can be achieved by etching off a portion of the outer circumference 241 of the contact pad 24 to form a recessed configuration during the etching process of the conductive circuit trace 11. Similar to the first and second embodiments described above, in the third embodiment of the present invention, the contact pad 24 can be a circular contact pad having a circular contour or circumference, a rectangular contact pad having a rectangular contour or circumference, or a gear-like contact pad having a toothed contour or circumference.

In a preferred embodiment of the present invention, the opening 31 of the insulation coverlay 3 has a diameter that is less than a diameter of the outer circumference 241 of the contact pad 24 (as shown in FIG. 4C). In other words, the insulation coverlay 3 has at least one hold-down section 33 overlapping and pressing down at least a portion of the outer circumference 241 of the contact pad 24. As such, when the insulation coverlay 3 is bonded by the adhesive layer 4 to the substrate 1, with the hold-down section 33 of the insulation coverlay 3 overlapping and pressing down the outer circumference 241 of the contact pad 24, the outer circumference of the contact pad 24 may not readily detach from the surface of the substrate 1 that is in engagement therewith.

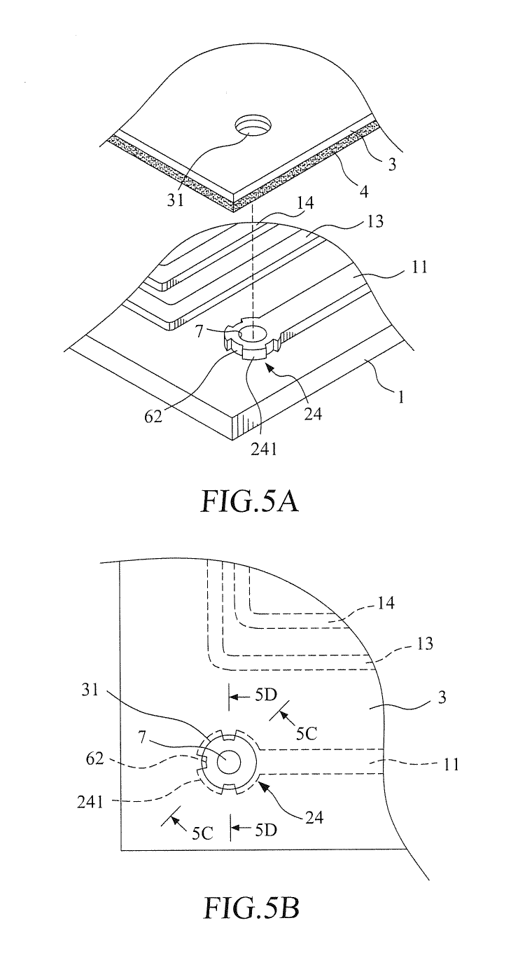

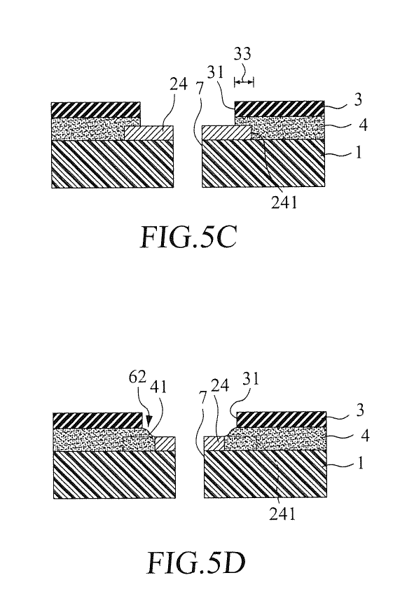

FIG. 5A is a schematic perspective view showing a conductive circuit trace and a pair of differential mode signal lines are formed on a substrate, an insulation coverlay is bonded on the substrate by an adhesive layer, and at least one spilled adhesive guide structure is formed in the conductive circuit trace according to a fourth embodiment of the present invention. FIG. 5B is a schematic top plan view showing the insulation coverlay is formed on the substrate of FIG. 5A. FIG. 5C is a cross-sectional view taken along line 5C-5C of FIG. 5B. FIG. 5D is a cross-sectional view taken along line 5D-5D of FIG. 5B. The instant embodiment has a structure that is substantially similar to that of the third embodiment illustrated in FIGS. 4A-4D and a difference is that a through hole 7 is formed in a central portion of the contact pad 24 and the through hole 7 also extends through the substrate 1 to receive a pin of an electronic component to penetrate through the through hole 7 for being subsequently fixed through soldering.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A flexible circuit board having a substrate provided with at least one conductive circuit trace thereon, at least one contact pad being defined on the conductive circuit trace, an insulation coverlay being adhesively bonded on the substrate by an adhesive layer, and the insulation coverlay comprising an opening formed therein to expose the contact pad;
wherein the conductive circuit trace comprises at least one spilled adhesive guide structure adjacent to the contact pad so that when the insulation coverlay is adhesively bonded by the adhesive layer to the conductive circuit trace, a spilled adhesive partially spilled out from the adhesive layer is guided into the spilled adhesive guide structure to prevent the spilled adhesive of the adhesive layer from covering the contact pad.

2. The flexible circuit board as claimed in claim 1, wherein the contact pad is a circular contact pad.

3. The flexible circuit board as claimed in claim 1, wherein the contact pad is a rectangular contact pad.

4. The flexible circuit board as claimed in claim 1, wherein the contact pad is a gear like contact pad.

5. The flexible circuit board as claimed in claim 1, wherein a conductive material is filled in the opening and the conductive material is in electrical engagement with the contact pad.

6. The flexible circuit board as claimed in claim 5, wherein the conductive material is selected from one of silver, aluminum, copper, tin, conductive carbon paste, and conductive particle contained adhesive.

7. A flexible circuit board having a substrate provided with at least one conductive circuit trace thereon, at least one contact pad being defined on the conductive circuit trace, the contact pad having an outer circumference, an insulation coverlay being adhesively bonded on the substrate by an adhesive layer, and the insulation coverlay comprising an opening formed therein to expose the outer circumference of the contact pad;
wherein the outer circumference of the contact pad comprises at least one spilled adhesive guide structure so that when the insulation coverlay is adhesively bonded by the adhesive layer to the conductive circuit trace, a spilled adhesive partially spilled out from the adhesive layer is guided into the spilled adhesive guide structure to prevent the spilled adhesive of the adhesive layer from covering the contact pad.

8. The flexible circuit board as claimed in claim 7, wherein the contact pad is a circular contact pad.

9. The flexible circuit board as claimed in claim 7, wherein the contact pad is a rectangular contact pad.

10. The flexible circuit board as claimed in claim 7, wherein the contact pad is a gear like contact pad.

11. The flexible circuit board as claimed in claim 7, wherein the contact pad comprises a through hole formed therein and the through hole extends through the substrate.

12. The flexible circuit board as claimed in claim 7, wherein the insulation coverlay comprises at least one hold-down section overlapping and pressing down the outer circumference of the contact pad.
